(19) United States
(12) Patent Application Publication
(10) Pub. No.: US 2005/0104087 A1
(43) Pub. Date: May 19, 2005

(54) InGaP pHEMT device for power amplifier operation over wide temperature range

(76) Inventors: Ellen Y. Lan, Chandler, AZ (US); Monica R. C. De Baca, Chandler, AZ (US); Bruce M. Green, Gilbert, AZ (US); Monte G. Miller, Phoenix, AZ (US); Charles E. Weitzel, Mesa, AZ (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/881,162

(22) Filed: Jun. 30, 2004

Related U.S. Application Data
(60) Provisional application No. 60/523,341, filed on Nov. 19, 2003.

(51) Int. Cl. H01L 31/0328; H01L 29/739

(52) U.S. Cl. 257/197

(57) ABSTRACT

In one embodiment, a semiconductor device (500) includes a buffer layer (504) formed over a substrate (502). An AlₓGa₁₋ₓAs layer (506) is formed over the buffer layer (504) and has a first doped region (508) formed therein. An InₓGa₁₋ₓAs channel layer (512) is formed over the AlₓGa₁₋ₓAs layer (506). An InₓGa₁₋ₓP barrier layer (518) is formed over the InₓGa₁₋ₓAs channel layer (512), the InₓGa₁₋ₓP layer (518) has a second doped region formed therein. A control electrode (526) is formed over the InₓGa₁₋ₓP layer (518). An undoped GaAs layer (520) is formed over the InₓGa₁₋ₓP layer (518) adjacent to the control electrode (526). A doped GaAs layer (524) is formed over the undoped GaAs layer (520) and on opposite sides of the control electrode (526) and provides first and second current electrodes. When used to amplify a digital modulation signal, the semiconductor device (500) maintains linear operation over a wide temperature range.

This application claims priority to provisional patent application Ser. No. 60/523,341, entitled “Using InGaP pHEMT for Power Amplifier Operation Over Temperature Using Digital Modulation,” Ellen Lan et al., filed Nov. 19, 2003.

### BACKGROUND

The present invention relates to the field of radio frequency power amplifiers, and more particularly to power amplifiers used in base stations under digital spread spectrum modulation and an InGaP pHEMT device for power amplifier operation over wide temperature range.

One example of spread-spectrum technology includes Wideband Code Division Multiple Access (WCDMA). WCDMA spreads multiple conversations across a wide segment of the spectrum as opposed to splitting a channel into time slots. With WCDMA, unique digital codes are used to differentiate subscribers that are simultaneously using the same spectrum.

In order to isolate conversations between two adjacent channels, a power amplifier used for WCDMA requires a certain level of linearity, characterized by an adjacent-channel power ratio (ACPR). As an example, an ACPR of −45 dBc (decibels with respect to the carrier) is specified as the linearity requirement for the active device in a power amplifier. Linear RF power amplifier manufacturers can utilize such a device having an ACPR at or below −45 dBc. The exact degree of linearity depends on the application and can vary widely.

In addition, base stations that utilize such a power amplifier are installed across the world and must be capable of operating over a wide range of temperatures to provide a desired level of service coverage. Accordingly, the RF power amplifier circuit should maintain performance over a temperature range on the order of −40° C. to +90° C. at its mounting base plate.

In radio frequency base station power amplifier operations, silicon LDMOS technology typically is used when frequency is below 2.5 GHz. However, silicon (Si) LDMOS has insufficient efficiency to meet competitive requirements above 2.5 GHz. Therefore, semiconductor technologies, such as GaAs (or AlGaAs) and GaN have been proposed and increasingly adopted. Typically, these are Metal Semiconductor Field Effect Transistors (MESFET) or High Electron Mobility Transistors (HEMT) including pseudomorphic High Electron Mobility Transistors (pHEMT).

When an AlGaAs pHEMT device is used for a power amplifier under digital spread spectrum modulation stimulus at −40° C., linear output power can degrade dramatically, as compared to room temperature. This level of power degradation phenomenon occurs under digital modulation, such as W-CDMA on the order of from 2 dB to 4 dB. However, little to no degradation is observed when the AlGaAs pHEMT device is operated under CW (continuous wave) stimulus at −40° C.

Accordingly, it would be desirable to provide for reduced power degradation under digital modulation over wide temperature operation for overcoming the problems in the art.

### SUMMARY

According to one embodiment, a novel power amplifier having a stable linear power operation over temperature, especially down to -40° C. is disclosed herein. The power amplifier includes a pHEMT structure having a InGaP material in the barrier layer of the pHEMT structure. The novel power amplifier can be included within a base station, a circuit, and for transmitting digital spread spectrum modulation.

### BRIEF DESCRIPTION OF THE DRAWINGS

The embodiments of the present disclosure are illustrated by way of example and not limited by the accompanying figures, in which like references indicate similar elements, and in which:

FIG. 1 is a cross-sectional view of an AlGaAs/InGaAs pHEMT device known in the art;

FIGS. 2(A and B) is a graphical view of current-voltage (IV) characteristics of the device of FIG. 1 at 25° C. and −40° C.;

FIG. 3 is a graphical view of continuous wave (CW) saturation characteristics of the device of FIG. 1 at 25° C. and −40° C.;

FIG. 4 is a graphical view of W-CDMA adjacent channel power ratio (ACPR) versus output power of the device of FIG. 1 at 25° C. and −40° C.;

FIG. 5 is a cross-sectional view of an InGaP/InGaAs pHEMT device according to one embodiment of the present disclosure;

FIG. 6 is a graphical representation of digital modulation signal operation of a power amplifier that includes an InGaP/InGaAs pHEMT device according to one embodiment of the present disclosure;

FIGS. 7(A and B) is a graphical view of current-voltage (IV) characteristics of the device of FIG. 5 according to an embodiment of the present disclosure at 25° C. and −40° C.;

FIG. 8 is a graphical view of continuous wave (CW) saturation characteristics of the device of FIG. 5 according to an embodiment of the present disclosure at 25° C. and −40° C.;

FIG. 9 is a graphical view of a W-CDMA adjacent channel power ratio (ACPR) versus output power of the device of FIG. 5 according to an embodiment of the present disclosure at 25° C. and −40° C.; and

FIG. 10 is a schematic diagram view of a power amplifier including the device of FIG. 5 according to an embodiment of the present disclosure.

Skilled artisans appreciate that elements in the figures are illustrated for simplicity and clarity and have not necessarily been drawn to scale. For example, the dimensions of some of the elements in the figures may be exaggerated relative to other elements to help improve an understanding of the embodiments of the present disclosure.

### DETAILED DESCRIPTION

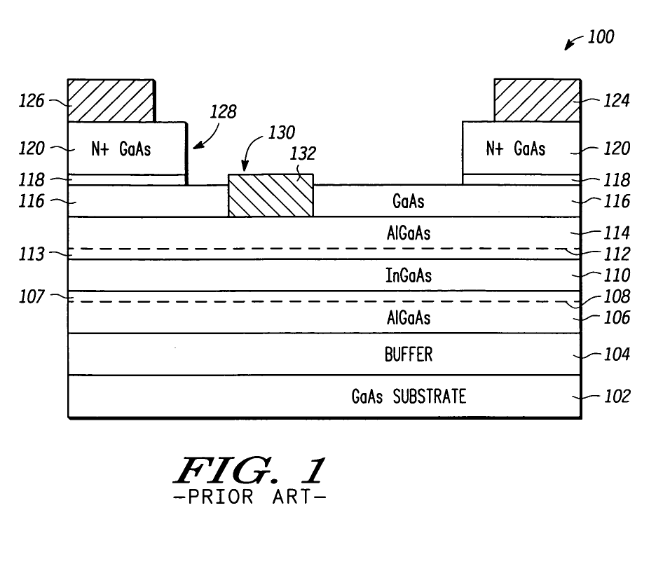

FIG. 1 is a cross-sectional view of an AlGaAs/InGaAs pHEMT device known in the art. The pHEMT device 100 is a double heterojunction structure that includes a GaAs substrate 102, a buffer layer 104, an initial portion of an AlGaAs layer 106, lower doping monolayer 108, a remaining portion of AlGaAs layer 107, InGaAs channel layer 110, an initial portion of an AlGaAs layer 113, upper doping monolayer 112, a remaining portion of AlGaAs layer 114, a GaAs layer 116, etch stop 118, and N+ GaAs ohmic contact regions 120. The pHEMT device 100 further includes metal electrodes 122, 124, and 126. Still further, pHEMT device 100 includes a dual recessed pHEMT device, wherein the first recess is generally indicated by reference numeral 128 and a second recess generally indicated by reference numeral 130. The configuration of the pHEMT device is asymmetrical as between the source 126 and gate 122 electrodes and the drain 124 and gate 122 electrodes. In the device 100 of FIG. 1, AlGaAs is used as a barrier layer material. Al_{0.24}Ga_{0.76} As is lattice matched to the underlying GaAs substrate 102.

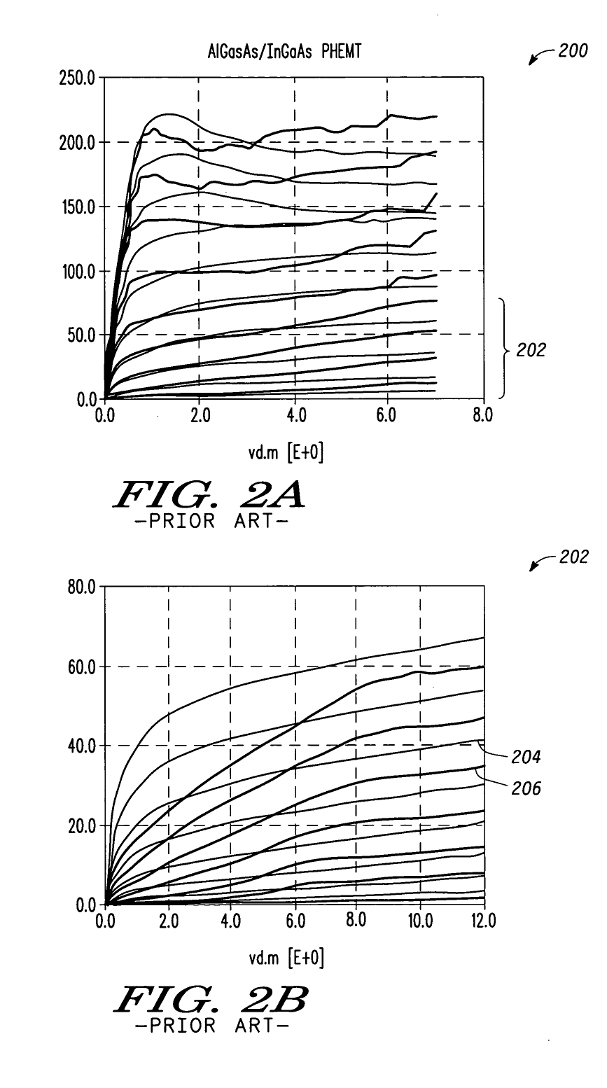

FIGS. 2(A and B) is a graphical view of DC current-voltage (IV) characteristics of the device of FIG. 1 at 25° C. and −40° C. In FIG. 2(A), an overall view of the DC IV characteristics is illustrated by the graph indicated by reference numeral 200, for drain biases from zero up to seven volts, and gate biases from the sub-threshold region to zero volts in 0.1 volt increments. A portion 202 of FIG. 2(A) is shown in FIG. 2(B) in an expanded view. In particular, the DC IV characteristics include drain biases from zero up to twelve volts, and gate biases starting at the sub-threshold region up to −0.6 volts, in 50 mV increments. Furthermore, at these lower current levels as shown in the portion 202, increased resistance and lower current are observed at −40° C. The curve indicated by reference numeral 204 is for device operation at temperature of 25° C. Whereas, the curve indicated by reference numeral 206 is for device operation at temperature of −40° C. Note that a shift in the threshold voltage is observed between device operation at the two temperatures.

As illustrated in FIG. 2, the drain current decreases when temperature of the device is lowered from room temperature of 25° C. to −40° C. In addition to the expected threshold shift, a decrease in drain current is believed to be due to the fact that AlGaAs has traps, and electrons remain trapped at −40° C. due to insufficient thermal energy. In an article [1] by R. Fischer, Timothy J. Drummond, J. Klem, W. Kopp, Timothy S. Henderson, Darren Perrachione, and Hadis Morkoc, “On the Collapse of Drain I-V Characteristics in Modulation-Doped FET's at Cryogenic Temperatures”, IEEE Transactions on Electron Devices, it has been reported that an AlGaAs pHEMT has drain current collapse characteristics at 77 K, or −196° C. due to DX centers. However, current collapse is not evident at Vgs=0 V in AlGaAs pHEMT device at −40° C., as illustrated in FIG. 2(A).

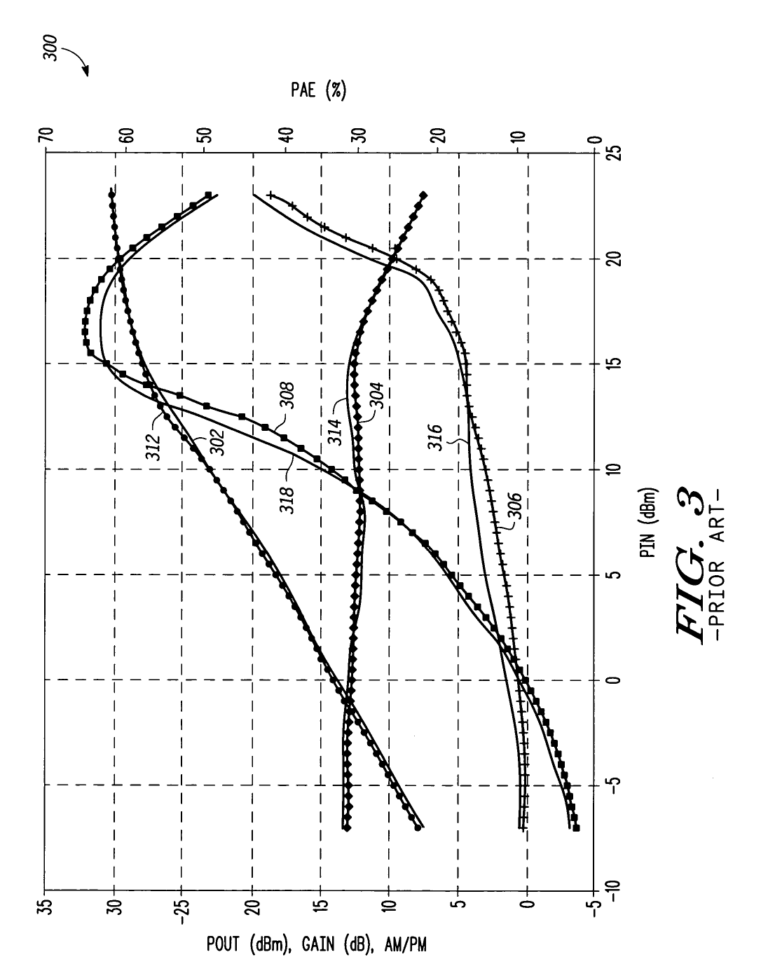

FIG. 3 is a graphical view of continuous wave (CW) saturation characteristics of the device 100 of FIG. 1 at 25° C. and −40° C. under 12V drain supply voltage. The output power (302), gain (304), insertion phase (AM-PM) (306), and power added efficiency (PAE) (308) are shown as a function of input power Pᵢₙ expressed in units of dBm at a temperature of 25° C. In addition, the output power (312), gain (314), insertion phase (AM-PM) (316), and power added efficiency (PAE) (318) are shown as a function of input power Pᵢₙ at a temperature of −40° C. As can be observed from the figure, there appears no appreciable change or deviation in these characteristics of device operation at the two temperatures 25° C. and −40° C.

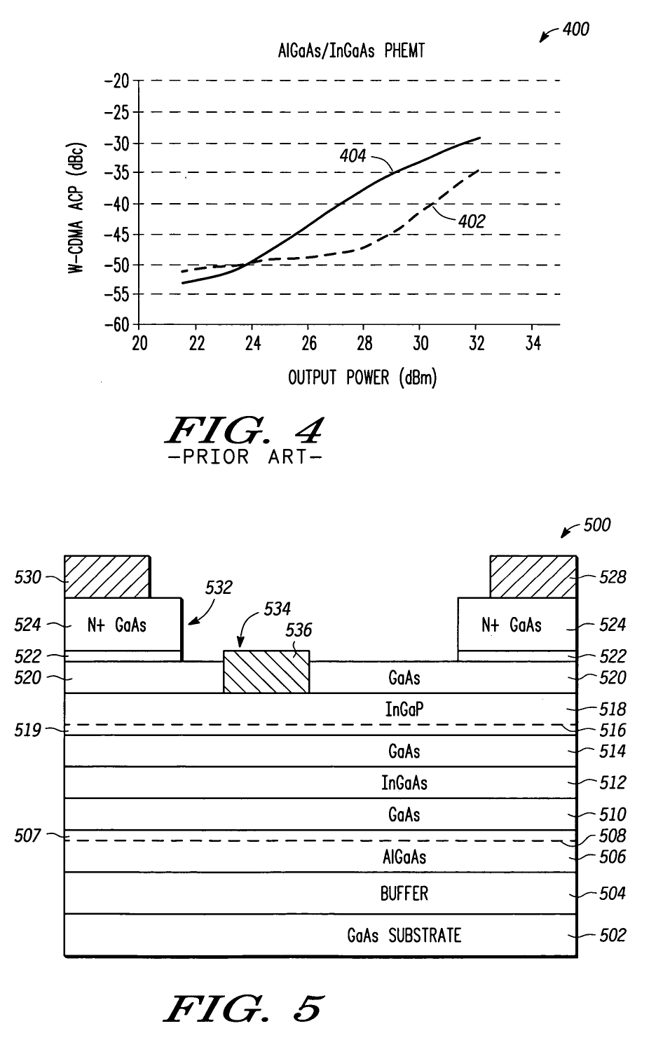

FIG. 4 is a graphical view 400 of a W-CDMA adjacent channel power ratio (ACPR) versus output power of the AlGaAs/InGaAs pHEMT device 100 of FIG. 1 at 25° C. and −40° C. under 12 V drain supply voltage. The device 100 operated at 25° C. results in the ACPR characteristic as illustrated by curve 402. At −40° C., however, the ACPR curve 404 is obtained. For a given linearity requirement (e.g., −45 dBc), a substantially lower output power is observed in curve 404 as compared with that of curve 402. In other words, curve 404 shifts upwards from that of curve 402, resulting in a substantial output power degradation in order to maintain the desired ACPR linearity requirement. Furthermore, a substantial output power degradation includes anything on the order of more than 1 dB. As shown in FIG. 4, the output power degradation illustrated by the difference between curve 404 and curve 402 is approximately 3.5 dB at the linearity requirement of −45 dBc.

FIG. 5 is a cross-sectional view of an InGaP/InGaAs pHEMT device according to one embodiment of the present disclosure. The pHEMT device 500 is a double heterojunction structure that includes a GaAs substrate 502, a buffer layer 504, an initial portion of an AlGaAs layer 506, lower doping monolayer 508, a remaining portion of AlGaAs layer 507, a bottom GaAs smoothing layer 510, an InGaAs channel layer 512, an upper GaAs smoothing layer 514, an initial portion of an InGaP barrier layer 519, upper doping monolayer 516, a remaining portion of InGaP barrier layer 518, a GaAs layer 520, etch stop 522, and N+ GaAs ohmic contact regions 524. The pHEMT device 500 further includes metal electrodes 526, 528, and 530. Still further, pHEMT device 500 includes a dual recessed pHEMT device, wherein the first recess is generally indicated by reference numeral 532 and a second recess generally indicated by reference numeral 534. The configuration of the pHEMT device is also asymmetrical as between the source 530 and gate 526 electrodes and the drain 528 and gate 526 electrodes.

According to one embodiment of the present disclosure, the pHEMT device structure 500 uses InGaP as a barrier layer material. In the particular InGaP pHEMT structure of FIG. 5, the barrier layer (518,519) includes In_{0.49}Ga_{0.51}P. Furthermore, In_{0.49}Ga_{0.51}P is lattice matched to the underlying GaAs substrate (502).

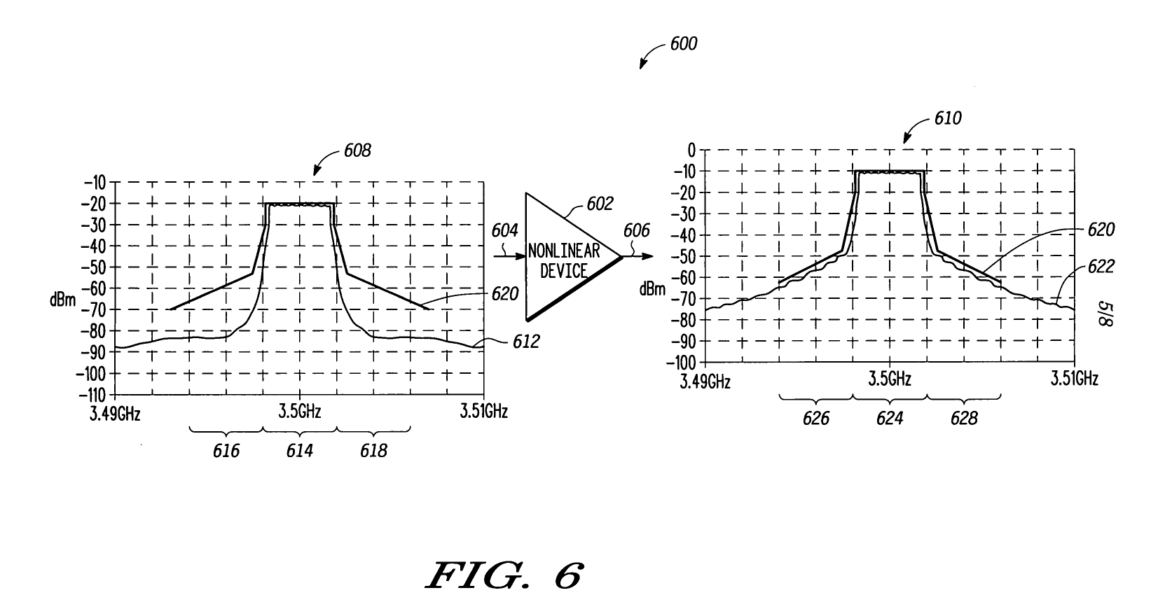

FIG. 6 is a graphical representation 600 of digital modulation signal operation of a power amplifier 602 that includes an InGaP/InGaAs pHEMT device 500 according to one embodiment of the present disclosure. Power amplifier 602 includes an input 604 and an output 606. One example of an input signal spectrum with a 3.5 GHz center frequency and a 3.84 MHz bandwidth is provided by the graphical representation indicated by reference numeral 608. In addition, one example of an output signal spectrum is provided by the graphical representation indicated by reference numeral 610.

Referring now to the spectrum 608, an actual input signal spectrum 612 includes portions in a main frequency channel 614, a lower adjacent frequency channel 616, and an upper adjacent frequency channel 618. In this instance, the power level of the input signal in an adjacent channel (616,618) is on the order of −60 dB below the power level in the main channel (614), corresponding to a −60 dBc adjacent channel power ratio (ACPR).

Referring now to the spectrum 610, an actual output signal spectrum 622 includes portions in a main frequency channel 624, a lower adjacent frequency channel 626, and an upper adjacent frequency channel 628. In this instance, the power level of the output signal in an adjacent channel (626,628) is on the order of −45 dB below the power level in the main channel (624), corresponding to a −45 dBc adjacent channel power ratio (ACPR).

In both spectrums 608 and 610, a spectrum mask 620 is shown. Spectrum mask 620 represents the ACPR specification that the output signal spectrum should remain below in order for the power amplifier 602 to be in compliance with the ACPR specification.

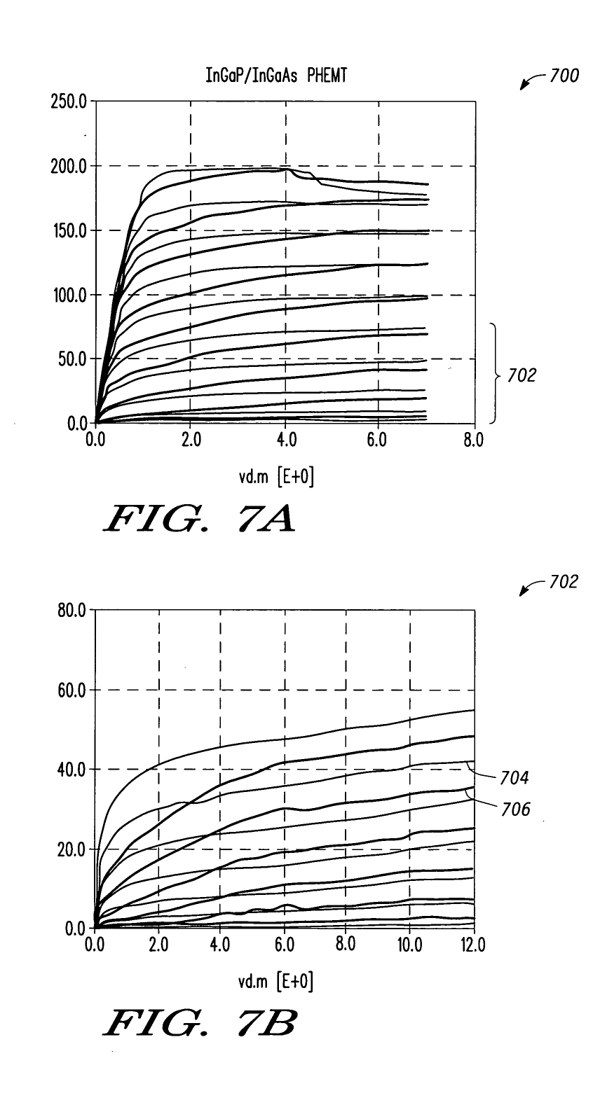

FIGS. 7(A and B) is a graphical view of DC current-voltage (IV) characteristics of the device of FIG. 5 according to an embodiment of the present disclosure at 25° C. and −40° C. In FIG. 7(A), an overall view of the DC IV characteristics is illustrated by the graph indicated by reference numeral 700, for drain biases from zero up to seven volts, and gate biases from the sub-threshold region to zero volts in 0.1 volt increments. A portion 702 of FIG. 7(A) is shown in FIG. 7(B) in an expanded view. In particular, the DC IV characteristics include drain biases from zero up to twelve volts, and gate biases starting at the sub-threshold region up to −0.6 volts, in 50 mV increments. Furthermore, at these lower current levels as shown in the portion 702, increased resistance and lower current are observed. The curve indicated by reference numeral 704 is for device operation at temperature of 25° C. Whereas, the curve indicated by reference numeral 706 is for device operation at temperature of −40° C. Note that a small shift in the threshold voltage is observed between device operation at the two temperatures.

Furthermore, as illustrated, the drain current decreases when temperature of the device is lowered from room temperature of 25° C. to −40° C. This is because InGaP has traps, and electrons remain trapped at −40° C. due to insufficient thermal energy. However, from the graphical representation of FIGS. 7 and 2, it is not obvious that the InGaP barrier pHEMT device 500 represented in FIG. 5 would degrade any less in the linear power at −40° C. than the AlGaAs barrier pHEMT device 100 represented in FIG. 1.

In an article [2] by Yi-Jen Chan, Dimitris Pavlidis, Manijeh Razeghi, and Frank Omnes, “GaInP/GaAs HEMT's Exhibiting Good Electrical Performance at Cryogenic Temperatures”, IEEE Transactions on Electron Devices, it has been reported that InGaP pHEMT does not show drain current collapse characteristics at 77 K, or −196° C., because it is a DX center free material. However, references [1] and [2] evaluated devices only at room temperature and −196° C. (77 K), and none of the data was taken at −40° C. Moreover, no radio frequency (RF) power performances at 77 K were presented in these references.

Furthermore, in an article [3] by S. F. Yoon, K. H. Yip, H. Q. Zheng, and B. P. Gay, “A Comparison of Deep Level Effects on the DC Characteristics of InGaP/InGaAs/GaAs and AlGaAs/InGaAs/GaAs High Electron Mobility Transistors Grown by Solid Source MBE”, 2001 International Conference on Indium Phosphide and Related Materials, it has been reported that DX center effect becomes significant only below 170 K, or −103° C., which is much lower than the temperature of interest with respect to the embodiments of the present disclosure, that is, −40° C.

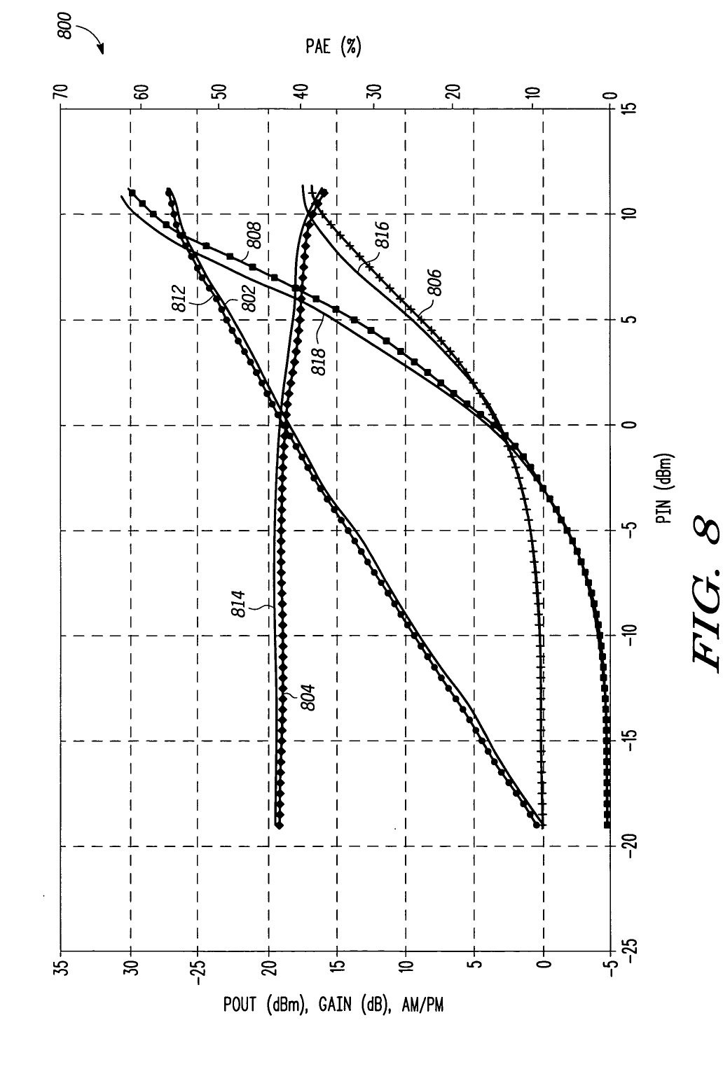

FIG. 8 is a graphical view of continuous wave (CW) saturation characteristics of the device of FIG. 5 according to an embodiment of the present disclosure at 25° C. and −40° C. under 12V drain supply voltage. The output power (802), gain (804), insertion phase (AM-PM) (806), and power added efficiency (PAE) (808) are shown as a function of input power Pᵢₙ expressed in units of dBm at a temperature of 25° C. In addition, the output power (812), gain (814), insertion phase (AM-PM) (816), and power added efficiency (PAE) (818) are shown as a function of input power Pᵢₙ at a temperature of −40° C. As can be observed from the figure, there appears no appreciable change or deviation in these characteristics of device operation at the two temperatures 25° C. and −40° C. Based upon these CW saturation characteristics 800 (FIG. 8) and the CW saturation characteristics 300 (FIG. 3), it is not obvious that the InGaP barrier pHEMT device 500 represented in FIG. 5 would degrade any less in the linear power at −40° C. than the AlGaAs barrier pHEMT device 100 represented in FIG. 1. In other words, under a CW stimulus at −40° C., little to no power degradation is observed for either of the AlGaAs pHEMT or InGaP pHEMT devices.

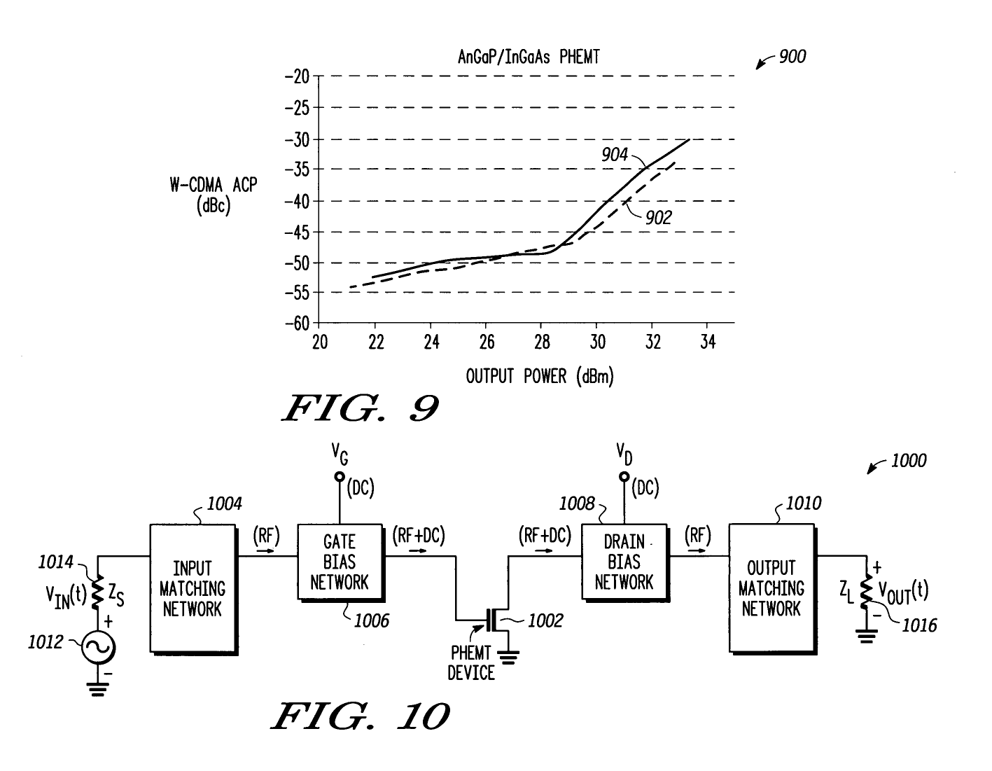

FIG. 9 is a graphical view 900 of a W-CDMA adjacent channel power ratio (ACPR) versus output power of the InGaP/InGaAs pHEMT device 500 of FIG. 5 according to an embodiment of the present disclosure at 25° C. and −40° C. under 12 V drain supply voltage. The device 500 operated at 25° C. results in the ACPR characteristic as illustrated by curve 902. At −40° C., the ACPR curve 904 is obtained. For a given linearity requirement (e.g., −45 dBc), a slightly lower output power is observed compared with that of curve 902. In other words, curve 904 shifts minimally upwards from that of curve 902, resulting in an acceptable output power degradation, for example, on the order of less than 1 dB. As shown, the output power degradation of curve 904 is approximately 0.4 dB. Accordingly, the device 500 maintains a desired linear output power from 25° C. to −40° C. when operated under digital modulation signal. Moreover, device 500 meets the desired ACPR linearity requirement, according to the embodiments of the present disclosure. In comparison, recall that the output power degradation as shown in FIG. 4 of prior art device 100 was on the order of 3.5 dB. W-CDMA linear power performance testing of pHEMT device 500 and pHEMT device 100 was conducted using same sized devices.

Turning now to Table I below, linear power data is shown for both the AlGaAs pHEMT device 100 and the InGaP pHEMT device 500 at room temperature and −40° C. With only 0.4 dB of degradation at −40° C., the InGaP pHEMT device 500 achieves stable W-CDMA power amplifier operation from room temperature to −40° C., compared to the known AlGaAs pHEMT device 100 which has 3.5 dB of degradation. Accordingly, the device 500 provides significant improvement in W-CDMA power amplifier operation over device 100.

TABLE I
Linear power performance of InGaP and AlGaAs pHEMT devices
at room temperature (+25° C.) and −40° C.

| | Output Power at - | Output Power at - | Output Power |
|---|---|---|---|
| | 45dBc_+25° C. (dBm) | 45dBc_−40° C. (dBm) | Drop (dB) |
| InGaP pHEMT device | 30.4 | 30.0 | 0.4 |
| (500) | | | |
| AlGaAs pHEMT device | 29.0 | 25.5 | 3.5 |
| (100) | | | |

Accordingly, the difference in output power degradation between that of device 500 and that of device 100 is on the order of 3.0 dB. In other words, for the InGaP/InGaAs pHEMT device 500, the power loss at −40° C. would be about eight percent (8%) of the original power at 25° C. Furthermore, the signal power maintained at −40° C. corresponds to ninety-two percent (92%) of the original power at 25° C. Whereas, for the AlGaAs/InGaAs pHEMT device 100, the power loss at −40° C. would be about fifty five percent (55%) of the original power at 25° C. Moreover, for the device 100, the signal power maintained at −40° C. corresponds to forty-five percent (45%) of the original power at 25° C. As a result, device 500 clearly demonstrates a capability to operate over a wide temperature range and maintain linear power level for a given ACPR linearity requirement.

FIG. 10 is a schematic diagram view of a power amplifier including the device of FIG. 5 according to an embodiment of the present disclosure. In particular, power amplifier 1000 includes InGaP pHEMT device 1002, input matching network 1004, gate bias network 1006, drain bias network 1008, and output matching network 1010. A radio frequency (RF) voltage source input VIN(t), that provides a modulated signal and is indicated by reference numeral 1012, couples to the input matching network 1004 via a source impedance Z_{S} indicated by reference numeral 1014. Input matching network 1004 outputs an RF signal, which is input to gate bias network 1006. Gate bias network 1006 includes a DC input, supplied by gate voltage supply V_{G}. Responsive to the RF signal and DC inputs, gate bias network 1006 outputs an RF+DC output signal that is applied to the gate of InGaP pHEMT device 1002. The source terminal of InGaP pHEMT device 1002 is coupled to ground potential. The drain terminal of InGaP pHEMT device 1002, which carries an RF+DC signal, is coupled to an input of drain bias network 1008. Drain bias network 1008 includes a DC input, supplied by drain voltage supply V_{D}. Responsive to the RF+DC and DC inputs, drain bias network 1008 outputs an RF output signal that is applied to the output matching network 1010. Output matching network 1010 outputs a V_{OUT}(t) signal across a load 1016 having an impedance Z_{L}.

According to one embodiment, a semiconductor device includes a substrate and a buffer layer formed over the substrate. An AlₓGa₁₋ₓAs layer is formed over the buffer layer, the AlₓGa₁₋ₓAs layer having a first doped region formed therein. As an alternate embodiment, an InₓGa₁₋ₓP layer having a doped region formed therein can replace the AlₓGa₁₋ₓAs layer. Following formation of the AlₓGa₁₋ₓAs layer, an InₓGa₁₋ₓAs layer is formed over the AlₓGa₁₋ₓAs layer. Then an InₓGa₁₋ₓP layer is formed over the InₓGa₁₋ₓAs layer, the InₓGa₁₋ₓP layer having a second doped region formed therein. A control electrode is formed over the InₓGa₁₋ₓP layer. In addition to formation of the control electrode, an undoped GaAs layer is formed over the InₓGa₁₋ₓP layer adjacent to the control electrode. Furthermore, a doped GaAs layer is formed over the undoped GaAs layer and on opposite sides of the control electrode, the doped GaAs layer for providing first and second current electrodes for the semiconductor device.

In another embodiment, the GaAs substrate is characterized as being a semi-insulating substrate. In addition, the semiconductor device can further include a GaAs smoothing layer between the AlₓGa₁₋ₓAs layer and the InₓGa₁₋ₓAs layer. Furthermore, the semiconductor device can also further includes a GaAs smoothing layer between the InₓGa₁₋ₓAs layer and the InₓGa₁₋ₓP layer. In yet another embodiment, the semiconductor device may still further include an AlAs or InGaP etch stop layer between the undoped GaAs layer and the doped GaAs layer.

In yet another embodiment, the control electrode is formed from titanium tungsten nitride (TiWN) or tungsten silicide (WSi). In addition, the semiconductor device may further include first and second metal source/drain contacts formed on the first and second current electrodes, respectively. In another embodiment, the semiconductor device is a pseudomorphic high electron mobility transistor (pHEMT), wherein the InₓGa₁₋ₓP layer functions as a barrier layer.

According to another embodiment, a method for forming a semiconductor device includes providing a substrate, forming a buffer layer over the substrate, and forming a bottom barrier layer over the buffer layer. The bottom barrier layer can include AlₓGa₁₋ₓAs or InₓGa₁₋ₓP. The method further includes forming an InₓGa₁₋ₓAs channel layer over the bottom barrier layer, forming an InₓGa₁₋ₓP barrier layer over the InₓGa₁₋ₓAs layer, forming an undoped GaAs layer over the InₓGa₁₋ₓP barrier layer, and forming a doped GaAs layer over the undoped GaAs layer. The doped GaAs layer includes a first recess formed therein that exposes a portion of the undoped GaAs layer. In addition, the method includes forming a control electrode within a second recess formed in the exposed portion of the undoped GaAs layer, wherein proximate opposite sides of the control electrode, the doped GaAs layer provides first and second current electrodes.

In another embodiment, forming the AlₓGa₁₋ₓAs barrier layer further comprises growing a first AlₓGa₁₋ₓAs layer having a first thickness, growing a silicon delta dopant on the first AlₓGa₁₋ₓAs layer, growing a second AlₓGa₁₋ₓAs layer on the silicon delta dopant having a second thickness, and growing a GaAs smoothing layer on the second AlₓGa₁₋ₓAs layer. In another embodiment, forming the InₓGa₁₋ₓP barrier layer further comprises growing a GaAs smoothing layer on the InₓGa₁₋ₓAs channel layer, growing a first InₓGa₁₋ₓP layer having a first thickness, growing a silicon delta dopant on the first InₓGa₁₋ₓP layer, and growing a second InₓGa₁₋ₓP layer on the silicon delta dopant having a second thickness.

The method of forming a semiconductor device further comprises growing an AlAs or InGaP etch stop layer on the patterned GaAs layer before forming the patterned doped GaAs layer. In one embodiment, forming the control electrode further comprises forming the control electrode from titanium tungsten nitride (TiWN) or tungsten silicide (WSi). Forming first and second current electrodes further comprises forming first and second metal source/drain contacts on the first and second current electrodes, respectively. Forming the control electrode further comprises asymmetrically positioning the control electrode between the first and second current electrodes.

According to another embodiment of the present disclosure, an amplifier includes a transistor, a gate bias network coupled to a control electrode of the transistor, and a drain bias network coupled to a first current electrode of the transistor. In one embodiment, the gate bias network comprises an input for receiving a digital modulation signal, wherein the digital modulation signal is characterized as being a wide-band code division multiple access (WCDMA) signal. The transistor further comprises first and second metal source/drain contacts formed on the first and second current electrodes, respectively.

The transistor includes a substrate, a buffer layer over the substrate, and a bottom barrier layer over the buffer layer. The bottom barrier layer can include AlₓGa₁₋ₓAs or InₓGa₁₋ₓP. The transistor further includes an InₓGa₁₋ₓAs channel layer formed over the bottom barrier layer, an InₓGa₁₋ₓP barrier layer formed over the InₓGa₁₋ₓAs layer, an undoped GaAs layer formed over the InₓGa₁₋ₓP barrier layer, and a doped GaAs layer formed over the undoped GaAs layer. The doped GaAs layer includes a first recess formed therein that exposes a portion of the undoped GaAs layer. In addition, the transistor includes a control electrode formed within a second recess, the second recess being formed in the exposed portion of the undoped GaAs layer, wherein proximate opposite sides of the control electrode, the doped GaAs layer provides first and second current electrodes. In one embodiment, the transistor is a pseudomorphic high electron mobility transistor (pHEMT). Furthermore, the control electrode is asymmetrically positioned between the first and second current electrodes. Moreover, the InₓGa₁₋ₓP layer functions as a barrier layer.

In the foregoing specification, the disclosure has been described with reference to various embodiments. However, one of ordinary skill in the art appreciates that various modifications and changes can be made without departing from the scope of the present embodiments as set forth in the claims below. Accordingly, the specification and figures are to be regarded in an illustrative rather than a restrictive sense, and all such modifications are intended to be included within the scope of the present embodiments.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A semiconductor device comprising:
a substrate;
a buffer layer formed over the substrate;
a bottom barrier layer formed over the buffer layer, the bottom barrier layer having a first doped region formed therein, wherein the bottom barrier layer comprises one selected from the group consisting of AlₓGa₁₋ₓAs and InₓGa₁₋ₓP;
an InₓGa₁₋ₓAs layer formed over the bottom barrier layer;
an InₓGa₁₋ₓP layer formed over the InₓGa₁₋ₓAs layer, the InₓGa₁₋ₓP layer having a second doped region formed therein;
an undoped GaAs layer formed over the InₓGa₁₋ₓP layer;
a doped GaAs layer formed over the undoped GaAs layer, the doped GaAs layer having a first recess formed therein that exposes a portion of the undoped GaAs layer; and
a control electrode formed within a second recess formed in the exposed portion of the undoped GaAs layer, wherein proximate opposite sides of the control electrode, the doped GaAs layer provides first and second current electrodes for the semiconductor device.

2. The semiconductor device of claim 1, wherein the GaAs substrate is characterized as being a semi-insulating substrate.

3. The semiconductor device of claim 1, further comprising a smoothing layer between the bottom barrier layer and the InₓGa₁₋ₓAs layer, wherein the smoothing layer comprises one selected from the group consisting of GaAs and AlₓGa₁₋ₓAs.

4. The semiconductor device of claim 1, further comprising a smoothing layer between the InₓGa₁₋ₓAs layer and the InₓGa₁₋ₓP layer, wherein the smoothing layer comprises one selected from the group consisting of GaAs and AlₓGa₁₋ₓAs.

5. The semiconductor device of claim 1, further comprising an etch stop layer between the undoped GaAs layer and the doped GaAs layer, wherein the etch stop layer comprises one selected from the group consisting of AlAs and InₓGa₁₋ₓP.

6. The semiconductor device of claim 1, wherein the control electrode comprises one selected from the group consisting of titanium tungsten nitride (Ti WN) and tungsten silicide (WSi).

7. The semiconductor device of claim 1, further comprising first and second metal source/drain contacts formed on the first and second current electrodes, respectively.

8. The semiconductor device of claim 1, wherein the semiconductor device is a pseudomorphic high electron mobility transistor (pHEMT).

9. The semiconductor device of claim 1, wherein the control electrode is asymmetrically positioned between the first and second current electrodes.

10. The semiconductor device of claim 1, wherein the InₓGa₁₋ₓP layer functions as a top barrier layer.

11. The semiconductor device of claim 1, wherein the semiconductor device is used for amplifying a digital spread spectrum modulation signal.

12. The semiconductor device of claim 11, wherein the digital spread spectrum modulation signal is a wide-band code division multiple access (WCDMA) signal.

13. A method for forming a semiconductor device comprising:
providing a substrate;
forming a buffer layer over the substrate;
forming a bottom barrier layer over the buffer layer, wherein the bottom barrier layer comprises one selected from the group consisting of AlₓGa₁₋ₓAs and InₓGa₁₋ₓP;
forming an InₓGa₁₋ₓAs channel layer over the bottom barrier layer;
forming an InₓGa₁₋ₓP barrier layer over the InₓGa₁₋ₓAs layer;
forming an undoped GaAs layer over the InₓGa₁₋ₓP barrier layer;
forming a doped GaAs layer over the undoped GaAs layer, the doped GaAs layer having a first recess formed therein that exposes a portion of the undoped GaAs layer; and
forming a control electrode within a second recess formed in the exposed portion of the undoped GaAs layer, wherein proximate opposite sides of the control electrode, the doped GaAs layer provides first and second current electrodes.

14. The method of claim 13, wherein forming the bottom barrier layer further comprises:
growing a first bottom barrier layer having a first thickness;
growing a silicon delta dopant on the first bottom barrier layer;
growing a second bottom barrier layer on the silicon delta dopant having a second thickness; and
growing a smoothing layer on the second bottom barrier layer, wherein the smoothing layer comprises one selected from the group consisting of GaAs and AlₓGa₁₋ₓAs.

15. The method of claim 13, wherein forming the InₓGa₁₋ₓP top barrier layer further comprises:
growing a smoothing layer on the InₓGa₁₋ₓAs channel layer, wherein the smoothing layer comprises one selected from the group consisting of GaAs and AlₓGa₁₋ₓAs;
growing a first InₓGa₁₋ₓP top barrier layer having a first thickness;
growing a silicon delta dopant on the first InₓGa₁₋ₓP top barrier layer; and
growing a second InₓGa₁₋ₓP top barrier layer on the silicon delta dopant having a second thickness.

16. The method of claim 13, further comprising growing an etch stop layer on the undoped GaAs layer before forming the doped GaAs layer, wherein the etch stop layer comprises one selected from the group consisting of AlAs and InₓGa₁₋ₓP.

17. The method of claim 13, wherein the control electrode comprises one selected from the group consisting of titanium tungsten nitride (TiWN) and tungsten silicide (WSi).

18. The method of claim 13, wherein forming first and second current electrodes further comprising forming first and second metal source/drain contacts on the first and second current electrodes, respectively.

19. The method of claim 13, wherein the semiconductor device is a pseudomorphic high electron mobility transistor (pHEMT).

20. The method of claim 13, wherein forming the control electrode further comprises asymmetrically positioning the control electrode between the first and second current electrodes.

21. The method of claim 13, wherein the semiconductor device is used for amplifying a digital spread spectrum modulation signal.

22. The method of claim 21, wherein the digital spread sprectrum modulation signal is a wide-band code division multiple access (WCDMA) signal.

23. An amplifier comprising:
a transistor comprising:
a substrate;
a buffer layer formed over the substrate;
an AlₓGa₁₋ₓAs layer formed over the substrate, the AlₓGa₁₋ₓAs layer having a first doped region formed therein;
an InₓGa₁₋ₓAs layer formed over the AlₓGa₁₋ₓAs layer;
an InₓGa₁₋ₓP layer formed over the InₓGa₁₋ₓAs layer, the InₓGa₁₋ₓP layer having a second doped region formed therein;
an undoped GaAs layer formed over the InₓGa₁₋ₓP layer;
a doped GaAs layer formed over the undoped GaAs layer, the doped GaAs layer having a first recess formed therein that exposes a portion of the undoped GaAs layer;
a control electrode formed within a second recess formed in the exposed portion of the undoped GaAs layer, wherein proximate opposite sides of the control electrode, the GaAs layer provides first and second current electrodes for the transistor;
a gate bias network coupled to the control electrode of the transistor; and
a drain bias network coupled to the first current electrode.

24. The amplifier of claim 23, wherein the gate bias network comprises an input for receiving a digital spread sprectrum modulation signal.

25. The amplifier of claim 24, wherein the digital spread spectrum modulation signal is characterized as being a wide-band code division multiple access (WCDMA) signal.

26. The amplifier of claim 23, wherein the transistor further comprises first and second metal source/drain contacts formed on the first and second current electrodes, respectively.

27. The amplifier of claim 23, wherein the transistor is a pseudomorphic high electron mobility transistor (pHEMT).

28. The amplifier of claim 23, wherein the control electrode is asymmetrically positioned between the first and second current electrodes.

29. The amplifier of claim 23, wherein the InₓGa₁₋ₓP layer functions as a barrier layer.
